(19) United States
(12) Patent Application Publication
(10) Pub. No.: US 2003/0142552 A1
(43) Pub. Date: Jul. 31, 2003

(54) Emulating volume having selected storage capacity

(75) Inventor: Robbie A. Green, Apopka, FL (US)

Correspondence Address: MORRIS, MANNING & MARTIN LLP, 6000 FAIRVIEW ROAD, SUITE 1125, CHARLOTTE, NC, 28210, US

(73) Assignee: Columbia Data Products, Inc., Altamonte Springs, FL (US)

(21) Appl. No.: 10/248,547

(22) Filed: Jan. 28, 2003

Related U.S. Application Data
(60) Provisional application No. 60/352,377, filed on Jan. 28, 2002.

(51) Int. Cl. G11C 5/00

(52) U.S. Cl. 365/189.01

(57) ABSTRACT

A volume having a selected storage capacity is emulated within a computer configuration by (a) representing to an operating system of the computer configuration the presence of the volume having the selected storage capacity and addresses for reading data therefrom and writing data thereto, (b) writing data to an address of the volume by, (i) writing the data to an address of a data store with which the volume address is associated, or (ii) writing the data to an address of the data store with which no volume address is associated, and associating the volume address with that data store address, and (c) reading data from a volume address by, (i) reading the data from a data store address with which the volume address has been associated in accordance with the writing step, or (ii) returning data that has not been written to the volume in the writing step.

### CROSS REFERENCE TO RELATED APPLICATIONS

This application claims the benefit under 35 U.S.C. §119(e) to the filing date of U.S. provisional patent application No. 60/352,377, titled, “Big Volume Emulator,” filed Jan. 28, 2002, which is incorporated herein by reference.

### APPENDIX DATA

Program Source Code Code.txt includes 3045 lines of code representing an implementation of a preferred embodiment of the present invention. The programming language is C++ and is intended to run on the Windows 2000 operating system. This program source code is incorporated herein by reference as part of the disclosure herein.

### BACKGROUND OF INVENTION

Software developers often write software for use by customers within computer configurations that the software developers simply cannot reproduce in actuality for testing purposes. In such situations, the software developers do their best to anticipate the behavior of their software within such computer configurations and, during the support phase of their software, the developers then address any computer configuration specific issues that may arise with particular implementations of their software.

As an example, a software program may be written and actually tested within computer configurations having ranges of storage capacities from 4 gigabytes (GB) of data storage up to 200 GB of data storage. Indeed, hard disk drives that may readily be purchased from a retail store include such ranges of storage capacities and are not cost prohibitive for testing by software developers. A 200 GB hard disk drive (“HDD”) currently costs about US$300. On the other hand, the software may be implemented by customers within computer configurations having more than 200 GB of data storage.

For instance, a customer may use the software within a computer configuration having several terabytes (TB) of data storage, wherein one TB equals 1,000 GB. Hardware having such storage capacities can be very expensive to purchase, especially if purchased for the sole purpose of software testing. Furthermore, the time required to format or otherwise preconfigure such hardware having large storage capacities, and then obtain relevant data from such hardware for analysis of the software operation, can be quite considerable. Thus, it can be cost prohibitive for software developers to test their software within computer configurations having such storage capabilities. Indeed, a one TB data storage device currently costs US$20,000 or more.

Additionally, the software ultimately may be used within computer configurations having petabytes (PB) of data storage, or even exabytes (EX) of data storage, especially if data storage devices continue their history of increased capacities at reduced prices. One PB equals 1,000 TB, and one EX equals 1,000 PB (i.e., 1,000,000,000,000,000,000 bytes). Ideally, software should be tested with computer configurations having data storage capacities spanning the possible range of future storage capacities even though such storage capacities currently are not commercially available to software developers, even if costs of testing were not a consideration.

Accordingly, a need exists for a method of testing software implementations within computer configurations without actually purchasing, preconfiguring, or managing such computer configurations and, specifically, a need exists for a method of emulating data storage capabilities within computer configurations for testing of software operations within such computer configurations, whether such computer configurations currently are available or merely are anticipated to be available in the future. One or more embodiments of the present invention meets such a need.

### SUMMARY OF INVENTION

In accordance with a first aspect of the present invention, hardware having a selected storage capacity within a computer configuration is emulated by (a) representing to an operating system of the computer configuration the presence of the hardware having the selected storage capacity and addresses for reading data therefrom and writing data thereto, (b) writing data to an address of the hardware by (i) writing the data to an address of a data store with which the hardware address is associated, or (ii) writing the data to an address of the data store with which no hardware address is associated, and associating the hardware address with that data store address, and (c) reading data from a hardware address by (i) reading the data from a data store address with which the hardware address has been associated in the writing step, or (ii) returning data that has not been written to the hardware in the writing step.

In accordance with a second aspect of the present invention, a volume having a selected storage capacity is emulated within a computer configuration by (a) representing to an operating system of the computer configuration the presence of the volume having the selected storage capacity and addresses for reading data therefrom and writing data thereto, (b) writing data to an address of the volume by, (i) writing the data to an address of a data store with which the volume address is associated, or (ii) writing the data to an address of the data store with which no volume address is associated, and associating the volume address with that data store address, and (c) reading data from a volume address by, (i) reading the data from a data store address with which the volume address has been associated in accordance with the writing step, or (ii) returning data that has not been written to the volume in the writing step.

A third aspect of the present invention relates to altering a computer configuration having an original volume with a first storage capacity to appear as a computer configuration having the original and an additional, readable/writable volume having a second, selected data storage capacity by (a) representing to an operating system of the computer configuration the presence of the additional volume, (b) writing data to an address of the volume by (i) writing the data to an address of a data store with which the volume address is associated, or (ii) writing the data to an address of the data store with which no volume address is associated, and associating the volume address with that data store address, and (c) reading data from a volume address by (i) reading the data from a data store address with which the volume address has been associated in the writing step, or (ii) returning data that has not been written to the volume in the writing step. In a feature of the present invention, the data store is maintained on the original volume and includes a data storage capacity that is less than the original volume.

Yet a fourth aspect of the present invention relates to emulating hardware having a selected storage capacity and selected storage characteristics within a computer configuration by, (a) representing to an operating system of the computer configuration the presence of the hardware having the selected storage capacity, selected storage characteristics, and addresses for reading data therefrom and writing data thereto, (b) writing data to an address of the hardware by (i) writing the data to an address of a data store with which the hardware address is associated, or (ii) writing the data to an address of the data store with which no hardware address is associated, and associating the hardware address with that data store address, and (c) reading data from a hardware address by (i) reading the data from a data store address with which the hardware address has been associated in the writing step, or (ii) returning data that has not been written to the hardware in the writing step.

### BRIEF DESCRIPTION OF DRAWINGS

Further features and benefits of the present invention will be apparent from a detailed description of preferred embodiments thereof taken in conjunction with the following drawings, wherein similar elements are referred to with similar reference numbers, and wherein,

FIG. 1 illustrates a conventional computer configuration.

FIG. 2 illustrates a computer configuration of a preferred embodiment of the present invention.

FIG. 3 illustrates another computer configuration of a preferred embodiment of the present invention.

FIG. 4 illustrates communications between an operating system of a computer configuration of a preferred embodiment of the present invention and disk drivers.

FIG. 5 illustrates a flowchart for a preferred embodiment of the present invention.

FIG. 6 illustrates a continuation of the flowchart of FIG. 5.

FIG. 7 illustrates an additional continuation of the flowchart of FIG. 5.

FIG. 8 illustrates a table of associations between EV Addresses and DS Addresses, and a data store, in accordance with a preferred embodiment of the present invention.

FIG. 9 illustrates a real volume and an associated emulated volume in accordance with FIG. 8.

### DETAILED DESCRIPTION

As a preliminary matter, it will readily be understood by those persons skilled in the art that the present invention is susceptible of broad utility and application in view of the following detailed description of preferred embodiments of the present invention. Many devices, methods, embodiments, and adaptations of the present invention other than those herein described, as well as many variations, modifications, and equivalent arrangements thereof, will be apparent from or reasonably suggested by the present invention and the following detailed description thereof, without departing from the substance or scope of the present invention. Accordingly, while the present invention is described herein in detail in relation to preferred embodiments, it is to be understood that this disclosure is illustrative and exemplary and is made merely for purposes of providing a full and enabling disclosure of preferred embodiments of the invention. The disclosure herein is not intended nor is to be construed to limit the present invention or otherwise to exclude any such other embodiments, adaptations, variations, modifications and equivalent arrangements, the present invention being limited only by the claims appended hereto or presented in any continuing application, and the equivalents thereof.

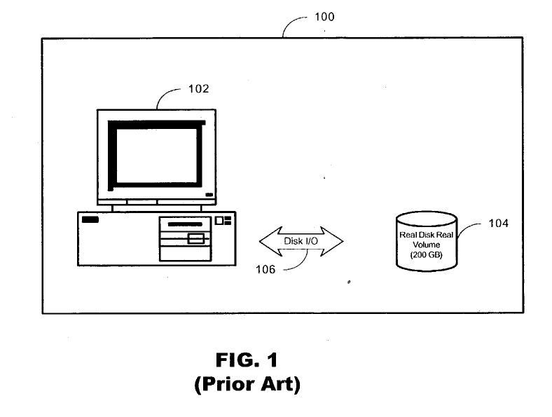

FIG. 1 illustrates a computer configuration 100 including a computer 102 and HDD that appears to the operating system as a volume 104 (hereinafter “Real Volume”) having, for example, a storage capacity of 200 GB. Indeed, a 200 GB HDD currently can be purchased at a typical computer retail store for about US$300. The computer 102 reads and writes data to the Real Volume 104 through disk input and output commands 106 (hereinafter “Disk I/O”). The computer configuration 100 may be used for purposes of testing an implementation of software within a computer configuration including a volume having a 200 GB storage capacity.

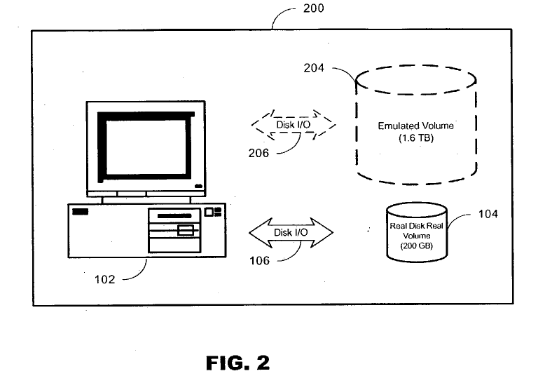

FIG. 2 illustrates a computer configuration 200 of a preferred embodiment of the present invention. As in the computer configuration 100, the computer configuration 200 includes a computer 102 and HDD that appears to the operating system as Real Volume 104 having, for example, a storage capacity of 200GB. The computer 102 also reads and writes data to the Real Volume 104 through Disk I/O 106. Unlike the computer configuration 100, however, the computer configuration 200 further includes an Emulated Volume 204 having a storage capacity, for example, of 1.6 TB to which the computer 102 reads and writes data through emulated Disk I/O 206.

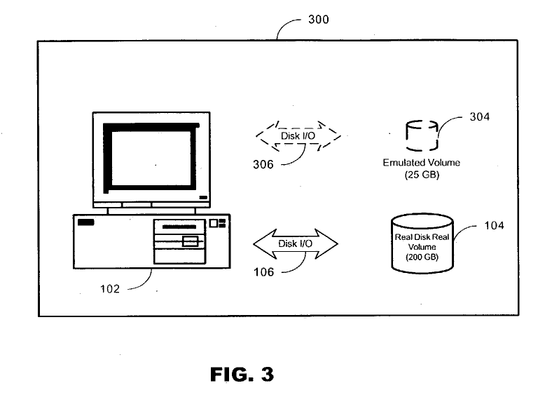

A second computer configuration 300 of a preferred embodiment of the present invention is similarly illustrated in FIG. 3. This computer configuration 300 is identical to the computer configuration 200 except that the Emulated Volume 304 has a storage capacity of 25 MB, instead of 1.6 TB, to which the computer 102 reads and writes data through emulated DISK I/O 306.

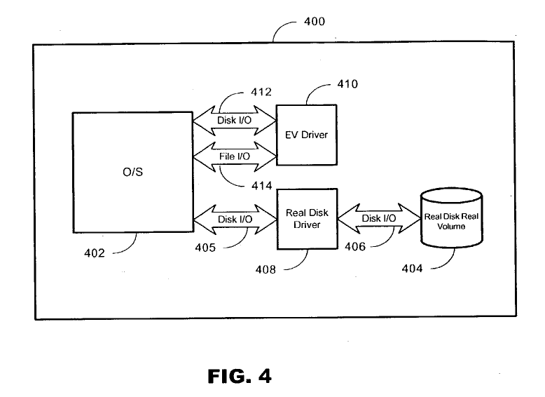

FIG. 4 illustrates a computer configuration of a preferred embodiment of the present invention with specific regard both to communications between the operating system (“O/S”) of a computer 402, a Real Volume 404, and a disk driver 408 of the Real Volume (“Real Disk Driver”); and to communications between the O/S of the computer 402 and a disk driver 410 of the Emulated Volume (“EV Driver”).

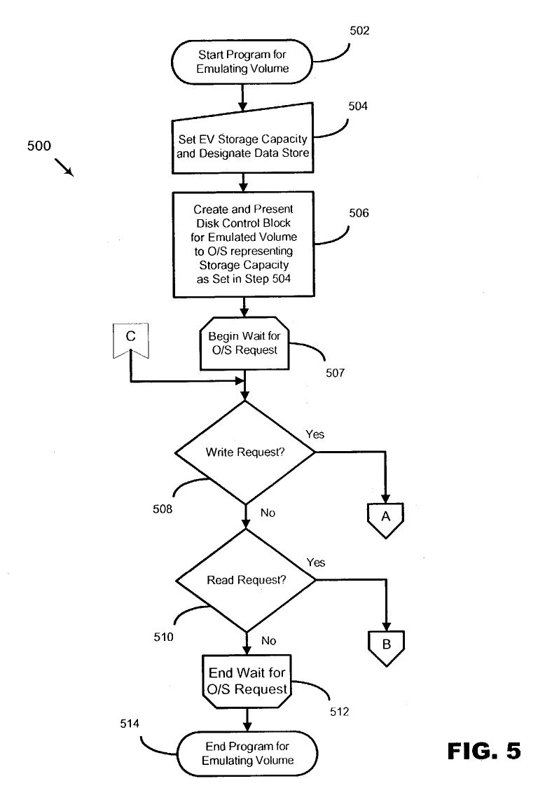

In particular, the O/S passes read and write requests to the Disk Driver 408 through Disk I/O 405. The Disk Driver 408, in turn, communicates disk read and write request through Disk I/O 406 to the Real Volume for block-specific reads and writes in conventional manner, as is known by those having ordinary skill in the art. The O/S passes read and write requests to the EV Driver through Disk I/O 412 also in conventional manner. However, rather than communicate disk read and write requests to an actual HDD, the EV Driver 410 communicates file read and write requests back to the O/S through file I/O 414. In turn, the O/S responds with resulting read and write requests to the Real Disk Driver 408 through Disk I/O 405 for the particular file read and writes requested by the EV Driver 410. In this manner, and in accordance with this preferred embodiment of the present invention, data written to the Emulated Volume is stored in and read from a file on the Real Volume, as now described in greater detail with reference to FIGS. 5-9.

In accordance with an embodiment 500 of a preferred method of the present invention, steps of which are illustrated in FIG. 5, during the initialization steps of a program for emulating a volume, both the storage capacity of the emulated volume is set and a data store for keeping data written to the emulated volume is designated (Step 504). During initialization of the program at Step 504, an index tree, such as a RB tree, also is setup. In a preferred embodiment, the index tree includes an entry for each address of the Emulated Volume.

A file preferably represents the data store for data written to and read from the emulated data storage, and this file and its location is identified during initialization at Step 504. Furthermore, preferably the data store preserves no data until the first write request is received in accordance with the illustrated method. If the data store is reused in emulating a new volume, the data store is preferably cleared during initiation.

In accordance with this embodiment, a disk control block for the emulated volume is created and presented (Step 506) to the operating system (“O/S”) of the computer configuration. This disk control block represents to the O/S that a volume having the storage capacity set in Step 504 is present within the computer configuration. The disk control block also may identify storage characteristics to the O/S, such as the number of heads, tracks, and sectors of a hard disk drive. In the source code attached, these characteristics are determined based on the storage capacity set in Step 504 during initialization of the program; however, these storage characteristics alternatively could be set, as well, to emulate a volume perhaps having the same storage capacity but otherwise different storage characteristics.

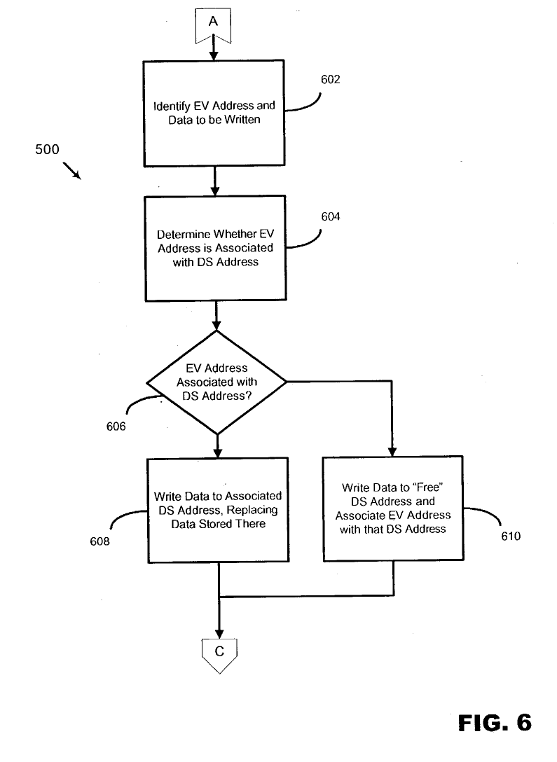

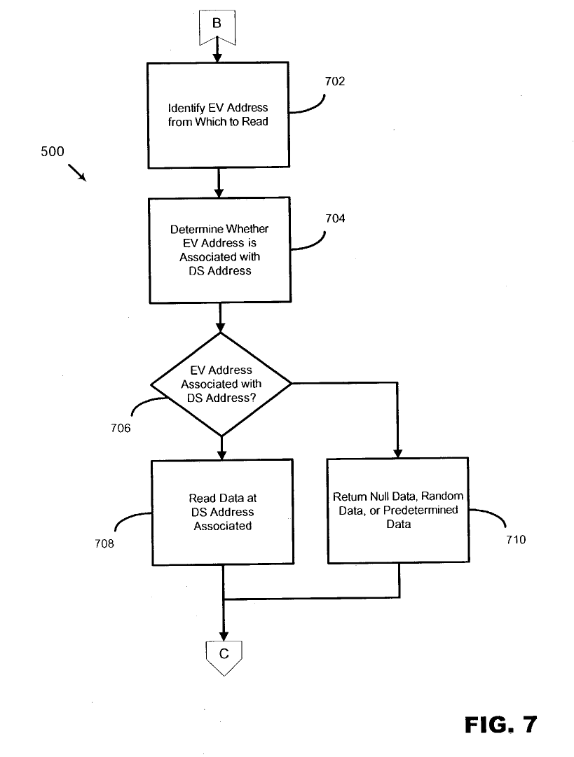

Thereafter, method 500 enters a loop 507,512 in which the method 500 waits for the O/S to present a request to the EV Driver. When a request is presented, a determination is made (Step 508) whether the request is a request to write data to the Emulated Volume and/or a determination is made (Step 510) whether the request is a request to read data from the Emulated Volume. If the request is to write data to the Emulated Volume, then the method 500 proceeds to the steps illustrated in FIG. 6, and if the request is to read data from the Emulated Volume, then the method 500 proceeds to the steps illustrated in FIG. 7. In either case, the method 500 returns at C to the loop 507,508, wherein it continues to wait for the next read or write request.

If the request is neither a write request nor a read request, then the request is passed on, such as to a lower driver, like a miniport driver found in the Windows 2000 operating system. For example, the request may include a request to close the volume or dismount the volume. Other such requests will be known to those having ordinary skill in the art.

The program exits (Step 512) the loop 507,508 upon one of many predetermined exit conditions. Such exit conditions also will be known to those having ordinary skill in the art. For example, the method 500 exits (Step 512) the loop 507,508 and ends (Step 514) upon the closing or dismounting of the Emulated Volume.

Turning to FIG. 6, upon the receipt of a write request, an address of the Emulated Volume (“EV Address”) specified in the write request together with data to be written at that address is identified (Step 602). The EV Driver then determines (Step 604) whether a EV Address is associated with the DS Address.

This determination preferably is made by referencing the index tree setup during initialization to determine if an index entry has been recorded for the EV Address. In particular, for each Emulated Volume Address to which data has been written, the entry in the index tree for that address includes a corresponding address within the data store (“DS Address”) to which the data actually has been written. An EV Address for which no data has been written will have no data in the data store and, thus, no corresponding DS Address will be referenced in its entry in the index tree.

If such an index entry is found, i.e., if an association is found at Step 606, then the data to be written at that address in the Emulated Volume is, in fact, written (Step 608) to the data store at the DS Address identified by the index entry, and the data currently at the DS Address is replaced with the new data.

If the EV Address is not found to be associated with a DS Address in Step 606, then a new association is made (Step 610) for the EV Address with a DS Address to which the data is written. Preferably, if an index entry is not found in the index tree for the EV Address, then a new index entry is made in the index tree for the EV Address. The data to be written is then written to a new location in the data store that is not yet associated with an EV Address, and the new DS Address for that location is recorded in the new index entry of the index tree. If no free DS Address is available, the Emulated Volume is determined to be full and an appropriate error indication is returned (not shown).

Turning to FIG. 7, an EV Address specified in the read request is identified (Step 702). The emulated volume driver then determines (Step 704) whether an EV Address is associated with the DS Address. If the EV Address is found to be associated with a DS Address at Step 704, then data has been written to the data store for the particular EV Address. In this situation, the data at the DS Address is read (Step 708) from the data store and returned to the O/S in response to the read request. If an index entry is not found for the EV Address, then null data is returned to the O/S in response to the read request. Alternatively, instead of null data, random data or predetermined data may be returned, as no data meaningful in and of itself is expected.

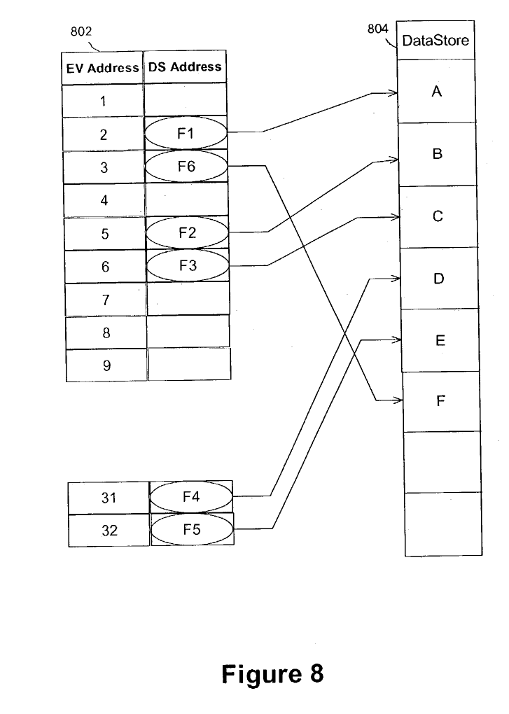

FIG. 8 illustrates associations of EV Addresses with DS Addresses in a table 802, and the corresponding data store 804 wherein the data written to the Emulated Volume is saved. As illustrated in FIG. 8, the table 802 includes 32 rows corresponding to 32 EV Addresses, with each row including a respective EV Address that comprises a key field of the table 802. A DS Address is identified in each row for which that EV Address is associated. Thus, for example, the table reveals that: EV Address 2 is associated with DS Address F1; EV Address 3 is associated with DS Address F6; EV Address 5 is associated with DS Address F2; EV Address 6 is associated with DS Address F3; EV Address 31 is associated with DS Address F4; and EV Address 32 is associated with DS Address F5.

The data store 804 comprises a file including locations therein F1, F2, F3, F4, F5, F6, F7, and F8. Furthermore, as illustrated F1 contains data “A”, F2 contains data “B”, F3 contains data “C”, F4 contains data “D”, F5 contains data “E”, and F6 contains data “F”. DS Addresses F7 and F8 contain no relevant data as of yet and are free.

Thus, for example, a read from the Emulated Volume in accordance with FIG. 8 of EV Address 2 returns “A”; of EV Address 3 returns “F”; of EV Address 5 returns “B”; of EV Address 6 returns “C”; of EV Address 31 returns “D”; and of EV Address 32 returns “E”. Furthermore, a read from the Emulated Volume in accordance with FIG. 8 of EV Address 1 returns “Z” (a predetermined arbitrary value, not shown) as does a read of EV Address 4.

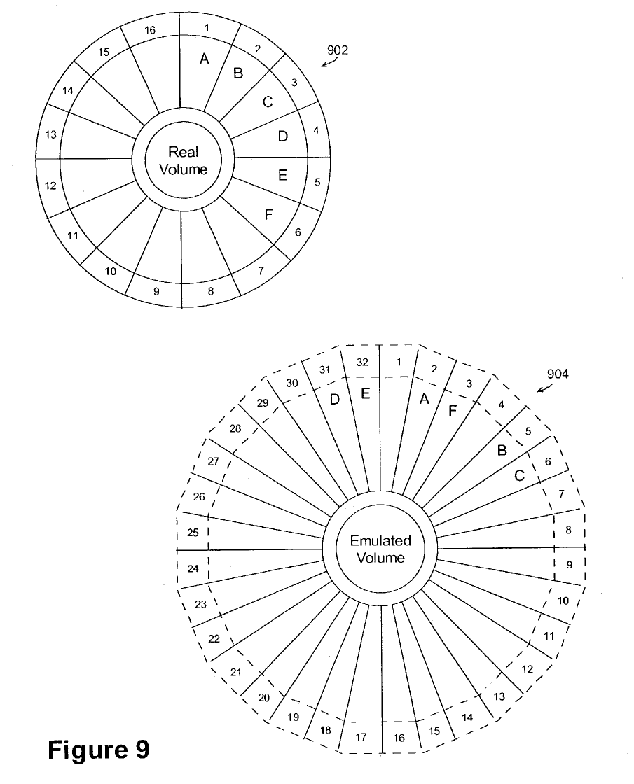

FIG. 9 illustrates a Real Volume 902 and an Emulated Volume 904 to which the table 802 and data store 804 of FIG. 8 pertain. As illustrated, the Real Volume includes 16 addresses (RV Addresses), and the Emulated Volume includes 32 EV Addresses. Furthermore, the data store comprising the file is actually located on the Real Volume at RV Addresses 1-8, which correspond, respectively, to DS Addresses F1-F8. The EV Volume includes six EV Addresses to which the data A-E has been written, namely, EV Addresses 2, 3, 5, 6, 31, and 32, and at least two additional writes to the Emulated Volume can be accommodated.

In view of the foregoing description, it will be apparent that an Emulated Volume having a wide range of storage capacities may be specified. For instance, the Emulated Volume may be set to have 1 MB of data storage or 1 EX of data storage in accordance with the present invention, regardless of the actual data storage capacity of the computer configuration, which may be less than, the same as, or more than the data storage of the Emulated Volume.

Thus, the present invention could be utilized in a computer configuration having a 500 MB HDD to represent a computer configuration having not only a 500 MB volume, but also having a 1 MB volume or a 2 GB volume. In either case, a portion of the 500 MB HDD is allocated as the data store to accommodate writes to the Emulated Volume. The data storage allocated to the data store may be 1 MB, 100 MB, or any size desired that is less than the actual data storage capability of the disk drive, after taking into account the data storage required for normal operations. The limit on the size of the Emulated Volume that is set is the allocated capacity of the data store that accommodates the data actually written to the EV Addresses of the Emulated Volume.

In addition to emulating data storage, it also should be noted that the software itself being tested, as well as other programs even including the O/S, can be copied onto the Emulated Volume for execution.

The computer configuration including the Emulated Volume of the present invention is well suited for testing software operations, especially for troubleshooting operations that result in cache overflow or would otherwise cause the O/S to crash. As will now be apparent, by utilizing the present invention the data on the Emulated Volume as it existed at the point in time of the crash can be read from the data store. Moreover, a convenient method for reading from the data store is to simply restart the program emulating the volume as shown in FIG. 5, but include the index tree at the time of the crash and designate the same file for the data store. The emulated volume then can be read in the sate in which it existed at the time of the crash. For example, a directory command can be executed to read the files and directories of the emulated volume. The present invention thus lends itself to software developers as an excellent debugging tool.

Furthermore, because of the convenient size of the data store (i.e., it only contains data written to the Emulated Volume, which may be only 1% or less of the emulated storage capacity), the data store can be copied and sent to others for additional analysis.

It may also be advantageous to study the course of changes in the data store as a function of time by recording and analyzing the state of the data store at periodic time intervals. Accordingly, in an aspect of the present invention, snapshots of the actual volume containing the data store and RB tree are taken at periodic intervals, whereby changes in the data store can be examined over time by reading snapshot data and reconstructing the Emulated Volume. Alternatively, snapshots of the Emulated Volume itself are taken at periodic intervals, whereby changes in the data store can be identified and examined over time by comparing the snapshots. Preferably, snapshots are taken in accordance with one or more methods and systems for taking snapshots as disclosed in U.S. patent application Ser. No. 10/248,483 and U.S. Provisional Patent Application Serial No. 60/350,434, the disclosure of each of which is expressly incorporated herein by reference.

In view of the foregoing detailed description of preferred embodiments of the present invention, it readily will be understood by those persons skilled in the art that the present invention is susceptible of broad utility and application. Thus, while the invention has been described within certain contexts of use, the invention may be useful in other contexts as well. Many embodiments and adaptations of the present invention other than those herein described in detail, as well as many variations, modifications, and equivalent arrangements, will be apparent from or reasonably suggested by the present invention and the foregoing description thereof, without departing from the substance or scope of the present invention.

Furthermore, any sequence(s) and/or temporal order of steps of various processes described and claimed herein are those considered to be the best mode contemplated for carrying out the present invention. It should also be understood that, although steps of various processes may be shown and described as being in a preferred sequence or temporal order, the steps of any such processes are not limited to being carried out in any particular sequence or order, absent a specific indication of such to achieve a particular intended result. In most cases, the steps of such processes may be carried out in various different sequences and orders, while still falling within the scope of the present inventions. In addition, some steps may be carried out simultaneously.

Accordingly, while the present invention has been described herein in detail in relation to preferred embodiments, it is to be understood that this disclosure is only illustrative and exemplary of the present invention and is made merely for purposes of providing a full and enabling disclosure of the invention. The foregoing disclosure is not intended nor is to be construed to limit the present invention or otherwise to exclude any such other embodiments, adaptations, variations, modifications and equivalent arrangements, the present invention being limited only by the claims appended hereto, or presented in any continuing application, and the equivalents thereof.

Thus, while a real HDD in each Figure has been referred to as a “Real Volume” for purposes of describing in detail the present invention, it will be apparent to one having ordinary skill in the art that the Real Volume may also represent a partition of a real HDD or real HDD array, and/or that the Emulated Volume may represent a partition of a HDD or of a HDD array. The HDD or HDD array also either may be locally connected to the computer or connected through a computer network. Therefore, while “volume” may be equated with “disk” in the illustrated preferred embodiments, “volume” nevertheless may also refer to other than a disk in other embodiments of the present invention, such as a partition of a disk or a logical partition that spans several hard disk drives. Furthermore, “computer configuration” may include not only a standalone computer, but also a computer network.

It will also be apparent that, within the scope of the present invention, the present invention may be utilized to emulate hardware having selected storage capacities within a computer configuration. Such emulated hardware may include other direct access storage devices (DASD) such as i-SCSI devices, SCSI devices, CD-R and DVD-R devices, CD-RW and DVD-RW devices, ATAPI devices, USB devices, block-serial devices (such as Tape drive devices), IDE devices, floppy devices, memory sticks, and ZIP and floppy disk devices. Storage characteristics apart from storage capacities may also be emulated.

Additionally, it will be apparent that, within the scope of the present invention, an EV Address may be associated with more than one DS Addresses. In this regard, the same data can be written to multiple EV Addresses of the Emulated Volume without increasing the data capacity of the data store; each EV Address to which the duplicate data is written would then be associated with a single DS Address at which the duplicate data resides. Other compression techniques also could be utilized within the scope of the present invention. For example, data comprised of a duplicate series of data byte(s) could be recorded without preserving the actual duplication of data bytes within the data store; only a single series of the data byte(s) need be preserved in the data store together with sufficient information regarding the repetition of the data byte series.

It will also be apparent that the data store need not comprise a file nor reside on the Real Volume. Instead, the data store may reside in computer RAM memory or some other storage location, such as, for example, read/write CDs or DVDs or a network share.

Multiple block reads and multiple block writes resulting from a single request (in which an address and an offset are specified) also are contemplated as being within the scope of the present invention.

1. An invention comprising a method for emulating a volume having a selected data storage capacity within a computer configuration, comprising the steps of,
(a) representing to an operating system of the computer configuration the presence of the volume having the selected storage capacity and addresses for reading data therefrom and writing data thereto,
(b) writing data to an address of the volume by either, (i) writing the data to an address of a data store with which the volume address is associated, or (ii) writing the data to an address of the data store with which no volume address is associated, and associating the volume address with that data store address, and
(c) reading data from a volume address by either, (i) reading the data from a data store address with which the volume address has been associated in accordance with said writing step, or (ii) returning data that has not been written to the volume in accordance with said writing step.

2. The invention of claim 1, wherein data compression is utilized in preserving data within the data store.

3. The invention of claim 1, wherein multiple addresses of the volume each is associated with the same data store address.

4. The invention of claim 1, further comprising indicating that the emulated volume is full when a data storage capacity of the data store is reached.

5. The invention of claim 1, wherein the emulated volume corresponds to an entire hard disk drive.

6. The invention of claim 1, wherein the emulated volume corresponds to a partition of a hard disk drive.

7. The invention of claim 1, wherein the emulated volume corresponds to a logical partition spanning multiple hard disk drives.

8. The invention of claim 1, further comprising the step of taking snapshots of the data store at periodic time intervals in order to analyze operation of software within such a computer configuration.

9. The invention of claim 8, wherein the step of taking snapshots includes taking snapshots of the location whereat the data store resides.

10. The invention of claim 8, wherein said step of taking snapshots includes taking snapshots of the emulated volume.

11. The invention of claim 1, wherein the selected data storage capacity is on the order of magnitude of megabytes.

12. The invention of claim 11, wherein the actual data storage capacity within the computer configuration itself is on the order of magnitude of one of megabytes, gigabytes, terabytes, petabytes and exabytes.

13. The invention of claim 1, wherein the selected data storage capacity is on the order of magnitude of gigabytes.

14. The invention of claim 13, wherein the actual data storage capacity within the computer configuration itself is on the order of magnitude of one of megabytes, gigabytes, terabytes, petabytes and exabytes.

15. The invention of claim 1, wherein the selected data storage capacity is on the order of magnitude of terabytes.

16. The invention of claim 15, wherein the actual data storage capacity within the computer configuration itself is on the order of magnitude of one of megabytes, gigabytes, terabytes, petabytes and exabytes.

17. The invention of claim 1, wherein the selected data storage capacity is on the order of magnitude of petabytes.

18. The invention of claim 17, wherein the actual data storage capacity within the computer configuration itself is on the order of magnitude of one of megabytes, gigabytes, terabytes, petabytes and exabytes.

19. The invention of claim 1, wherein the selected data storage capacity is on the order of magnitude of exabytes.

20. The invention of claim 19, wherein the actual data storage capacity within the computer configuration itself is on the order of magnitude of one of megabytes, gigabytes, terabytes, petabytes and exabytes.

21. The invention of claim 1, wherein said step of returning data that has not been written in accordance with said writing step comprises returning null data.

22. The invention of claim 1, wherein said step of returning data that has not been written to in accordance with said writing step comprises returning random data.

23. The invention of claim 1, wherein said step of returning data that has not been written to in accordance with said writing step comprises returning the same data in each such instance.

24. The invention of claim 1, wherein said step of returning data that has not been written to in accordance with said writing step comprises returning data that is meaningless in and of itself.

25. The invention of claim 1, wherein the data store comprises a disk.

26. The invention of claim 1, wherein the data store comprises a partition.

27. The invention of claim 1, wherein the data store comprises a file.

28. The invention of claim 1, wherein the data store comprises a data storage area in RAM memory of the computer configuration.

29. The invention of claim 1, wherein the data store comprises a network share.

30. The invention of claim 1, wherein the selected storage capacity is equal to the actual storage capacity of any real volume within the computer configuration.

31. The invention of claim 1, wherein the selected storage capacity is different from the actual storage capacity of any real volume within the computer configuration.

32. The invention of claim 1, wherein the selected storage capacity is greater than the actual storage capacity of any real volume within the computer configuration.

33. The invention of claim 1, wherein the selected storage capacity is less than the actual storage capacity of any real volume within the computer configuration.

34. The invention of claim 1, wherein the selected storage capacity is on the order of magnitude of one of terabytes, petabytes, and exabytes, and further comprising the step of analyzing with others an operation of software within such a computer configuration by communicating the data store over the Internet.

35. The invention of claim 1, wherein the selected storage capacity is on the order of magnitude of one of terabytes, petabytes, and exabytes, and further comprising the step of analyzing with others an operation of software within such a computer configuration by communicating the data store on one of the group of a floppy disk, a compact disc, a DVD disc, a Zip disk, and a USB storage device.

36. An invention comprising a computer-readable medium having computer-executable instructions for performing the method of claim 1.

37. An invention comprising a computer configuration including computer-readable media having computer-executable instructions for performing the method of claim 1.

38. An invention comprising a computer-readable medium having computer-executable instructions for performing a method for emulating a volume within a computer configuration, the method including
(a) a step for representing to an operating system of the computer configuration the presence of the volume having the selected storage capacity and addresses for reading data therefrom and writing data thereto,
(b) a step for writing data to an address of the volume by either, (i) writing the data to an address of a data store with which the volume address is associated, or (ii) writing the data to an address of the data store with which no volume address is associated, and associating the volume address with that data store address, and
(c) a step for reading data from a volume address by either, (i) reading the data from a data store address with which the volume address has been associated in accordance with said writing step, or (ii) returning data that has not been written to the volume in accordance with said writing step.

39. An invention comprising a computer configuration including computer-readable media having computer-executable instructions for performing a method for emulating a volume within a computer configuration, the method including,
(a) a step for representing to an operating system of the computer configuration the presence of the volume having the selected storage capacity and addresses for reading data therefrom and writing data thereto,
(b) a step for writing data to an address of the volume by either, (i) writing the data to an address of a data store with which the volume address is associated, or (ii) writing the data to an address of the data store with which no volume address is associated, and associating the volume address with that data store address, and
(c) a step for reading data from a volume address by either, (i) reading the data from a data store address with which the volume address has been associated in accordance with said writing step, or (ii) returning data that has not been written to the volume in accordance with said writing step.

40. An invention comprising a computer-readable medium having computer-executable instructions for performing a method for emulating a volume within a computer configuration, the computer-executable instructions including,
(a) means for representing to an operating system of the computer configuration the presence of the volume having the selected storage capacity and addresses for reading data therefrom and writing data thereto,
(b) means for writing data to an address of the volume by either, (i) writing the data to an address of a data store with which the volume address is associated, or (ii) writing the data to an address of the data store with which no volume address is associated, and associating the volume address with that data store address, and
(c) means for reading data from a volume address by either, (i) reading the data from a data store address with which the volume address has been associated in accordance with said writing step, or (ii) returning data that has not been written to the volume in accordance with said writing step.

41. An invention comprising computer configuration in which a volume within the computer configuration is emulated, the computer configuration including,
(a) means for representing to an operating system of the computer configuration the presence of the volume having the selected storage capacity and addresses for reading data therefrom and writing data thereto,
(b) means for writing data to an address of the volume by either, (i) writing the data to an address of a data store with which the volume address is associated, or (ii) writing the data to an address of the data store with which no volume address is associated, and associating the volume address with that data store address, and
(c) means for reading data from a volume address by either, (i) reading the data from a data store address with which the volume address has been associated in accordance with said writing step, or (ii) returning data that has not been written to the volume in accordance with said writing step.
